(19) United States
(12) Patent Application Publication
(10) Pub. No.: US 2010/0159672 A1
(43) Pub. Date: Jun. 24, 2010

(54) METHOD AND DEVICE FOR CLEANING ELECTRONIC COMPONENTS PROCESSED WITH A LASER BEAM

(75) Inventors: Joannes Leonardus Jurriam Zijl, Ede (NL); Henri Joseph Van Egmond, Ede (NL)

Correspondence Address: NIXON & VANDERHYE, PC, 901 NORTH GLEBE ROAD, 11TH FLOOR, ARLINGTON, VA, 22203, US

(73) Assignee: FICO B.V., RW Duiven (NL)

(21) Appl. No.: 11/993,238

(22) PCT Filed: Jun. 15, 2006
(86) PCT No.: PCT/NL06/50138

§ 371 Date: Apr. 9, 2008

(30) Foreign Application Priority Data
Jun. 30, 2005 (NL) 1029378

(51) Int. Cl. H01L 21/268; B23K 26/00

(52) U.S. Cl. 438/463; 219/121.67; 257/E21.347

(57) ABSTRACT

The present invention relates to a method for processing with a laser beam and cleaning electronic components, wherein at least one new boundary surface is formed on an electronic component with the laser beam. The invention also relates to a device for processing and cleaning electronic components, comprising at least: a laser source for generating a laser beam, and at least one carrier for supporting an assembly of unseparated electronic components, wherein the carrier and the laser beam are displaceable relative to each other.

The present invention relates to a method for processing with a laser beam and cleaning electronic components, wherein at least one new boundary surface is formed on an electronic component with the laser beam. The invention also relates to a device for processing and cleaning electronic components as according to the preamble of claim 15.

In the production of semiconductor products it is usual for a large number of products to be joined together in a combined assembly of semiconductor products (which is also referred to for instance as a lead frame or a board). After completion of the greater part of the production steps the combined semiconductor products are separated from each other by a machining or cutting operation. Use is also made for this purpose of laser cutting technique. A significant drawback of the existing laser cutting techniques is that the separated components become contaminated as a result of the laser cutting. This can be explained by, among other reasons, evaporation of material (for instance metals, hydrocarbons which may or may not be fully combusted and which come from glue, epoxy and so forth) and the subsequent deposition of this material on the electronic components. The deposition consists of for instance the polymer and the filling material of the plastic from which the encapsulation is manufactured, such as inorganic oxides and more in particular silicon oxides. The contamination of the semiconductor products processed with a laser beam is particularly persistent at the position of the newly made boundary surfaces, since these surfaces usually have a less smooth surface, as a result of which contamination will particularly accumulate in lower portions of the these boundary surfaces made by laser beams. In the use of laser separation technique in the processing of semiconductor products such contamination is undesirable or unacceptable.

The invention has for its object to provide a solution with which the contamination of the electronic components processed with a laser can be combatted, particularly at the position where new boundary surfaces are created as a result of processing the electronic components with a laser beam.

The invention provides for this purpose a method as according to claim 1. At least two electronic components are preferably separated from each other during processing step A). It is precisely the new boundary surface, or new boundary surfaces, of an electronic component which usually has or have a rougher surface structure. It is usually precisely this rougher surface which will be relatively heavily contaminated, partly because the laser process has also taken place specifically at that position. Cleaning the rougher boundary surface (external surface) by means of mechanical cleaning is difficult, and has the drawback of a great chance of damage to the electronic components. It is specifically the cleaning of electronic components in combination with a laser beam process (such as for instance laser cutting) which now has the advantage that the lower-lying parts and irregularly formed recesses of the new boundary surface can also be cleaned extremely well because of the cavitation occurring during ultrasonic cleaning (imploding gas bubbles of small size in the cleaning liquid). Particularly described in this application is the simultaneous cleaning of a plurality of electronic components, since it is generally the case in practice that larger matrices of individual electronic components are separated and subsequently further processed; this is not essential however. An individual electronic component can also be cleaned in accordance with the same method and in the same device. The cleaning of individual electronic components therefore also falls within the scope of protection being sought.

It is desirable here to place the electronic components for cleaning in a liquid, which can be realized in simple manner by placing the electronic components wholly or partially, subject to the conditions, in a liquid bath. An electronic component can thus be fully cleaned externally during processing step B), although it is also possible, depending on the desired cleaning, to envisage cleaning only a part of the external surface. This may be desirable for instance in the case ultrasonic cleaning of an electronic component has adverse consequences for a part of the surface of an electronic component that is fully cleaned externally.

The electronic components are preferably cleaned at a frequency higher than 18 kHz, preferably higher than 20 kHz. In order to optimize the cleaning process it is possible to vary a number of process parameters such as the frequency; this normally lies between 20 and 150 kHz, more particularly between 20 and 50 kHz. Other process parameters are temperature, time, composition of the cleaning liquid, presence of gas in the liquid and so forth, and further reference will be made hereto below.

A further improvement of the cleaning result can be obtained in that during processing step B) the electronic components for cleaning are carried into the liquid by a manipulator such that during the cleaning the manipulator is located on the side of the electronic component remote from an ultrasonic vibration source. The manipulator does not therefore form a barrier in order to obtain as much cavitation as possible on the surface for cleaning/surfaces for cleaning of the electronic component. The mutual distance between a plurality of electronic components to be simultaneously cleaned can also be made greater during cleaning according to processing step B) than the mutual distance between the same electronic components during processing step A). Moving the components further apart (by moving them apart in the plane in which they are situated and/or by moving some of the components out of the plane in which they initially lie) causes less of an obstacle to obtaining a considerable cavitation on the surface for cleaning/the surfaces for cleaning of the electronic component.

Another measure for enhancing the cleaning result relates to heating of the liquid in which the ultrasonic cleaning is carried out to more than 20° C., preferably to more than 30° C. An increased temperature brings about an improved cleaning result. Only a limited increase in temperature of the liquid to more than 20° C., or still better to more than 30° C., can already result in a considerable improvement in the cleaning. Depending on the conditions, it is also possible to opt for heating the liquid more such that it reaches a temperature of more than 40° C., or even more than 50° C. It is also advantageous if the liquid is degassed before it is used in the ultrasonic cleaning; an improved cleaning action is thus obtained.

It is simplest to have the liquid in which the ultrasonic cleaning is performed consist substantially of water. One or more surfactants can advantageously be added to this water, or to another starting liquid, in which the ultrasonic cleaning is performed. A surfactant is understood to mean a surface-active agent such as for instance soap, water-soluble alkanols such as for instance methanol, ethanol and isopropanol, water-soluble ketones such as methyl ethyl ketone, dimethyl ketone, diethyl ketone, and/or glycols. It is also advantageous for increasing the cavitation if the liquid under which the ultrasonic cleaning takes place is degassed prior to the ultrasonic cleaning.

A further measure for enhancing the result of the ultrasonic cleaning consists of cleaning the liquid under which the ultrasonic cleaning takes place. This is possible for instance by regularly refreshing the liquid, filtering the liquid, removing deposition and so forth.

After the ultrasonic cleaning the liquid adhering to the electronic components can be actively removed; for instance by means of suctioning off the liquid, this being recommended because the liquid is then discharged in controlled manner. Alternatively, it is also possible to blow on or wipe off the electronic components such that adhering liquid is removed. This has the advantage that not only is the liquid removed, but also the contamination present in the liquid.

The present invention furthermore provides a device for processing and cleaning electronic components as according to claim 15. By means of such a device the advantageous cleaning possibilities can be obtained as already described above with reference to the method according to the present invention. The ultrasonic cleaning means preferably comprise a liquid bath and at least one vibration source connecting to the liquid bath. An ultrasonic cleaning can now be generated in the liquid bath by the vibration source. A more effective cleaning can be obtained when a plurality of vibration sources are used. The manipulator and the liquid bath are also dimensioned here such that the electronic components held by the manipulator can be placed partially or fully in the liquid bath.

In yet another embodiment variant the manipulator is rotatable, whereby the electronic components for cleaning are placed in the liquid bath by the manipulator such that during cleaning the manipulator is located on the side of the electronic components remote from the vibration source. The manipulator does not therefore form an obstacle between the vibration source and the components for cleaning.

The manipulator can also take a multiple form such that during cleaning of the electronic components an engaging part of the manipulator lies at a distance from the cleaning means. The advantage here can be that, during performing of the ultrasonic cleaning of some electronic components, the engaging part of the manipulator lying at a distance from the cleaning means can simultaneously be loaded elsewhere with a subsequent batch of electronic components for processing and/or an already cleaned batch of electronic components can be offloaded therefrom. The critical path of the processing steps performed with the manipulator is thus shortened considerably.

The device can be provided with suction openings engaging by means of underpressure on the electronic components, for instance suction openings formed by the outer ends of tubular contact elements. The engaging and release of large numbers of very small components using such a manipulator can be realized efficiently. The advantage of the tubular contact elements is that a large part of the manipulator can thus be held at a distance from the electronic components; this can result in less disruption of the ultrasonic cleaning. It is also possible to provide the manipulator with a plurality of engaging positions, the mutual distance of which is adjustable. This can also bring about, as already described above with reference to the present method, an improved cleaning result.

In order to heat the liquid bath the ultrasonic cleaning means are provided with heating means. The liquid bath can likewise connect to dispensing means for supplying an additive. See the description above of the method according to the present invention for further elucidation. If the ultrasonic cleaning means are also provided with at least one actuator for displacing the liquid in the liquid bath, a liquid flow or liquid turbulence can be generated; once again in order to enhance the cleaning action. The cleaning means can also be provided with cleaning means for cleaning the liquid in the liquid bath.

Another advantageous embodiment variant of the device is provided with means for removing adhering liquid from the electronic components cleaned by the ultrasonic cleaning means. This is possible for instance with a suction means which suctions off liquid adhering to a single side or to both sides of the electronic components. It is on the other hand also possible to blow on the cleaned electronic components such that the liquid adhering to the electronic components is removed therefrom.

The present invention will be further elucidated on the basis of the non-limitative exemplary embodiments shown in the following figures. Herein:

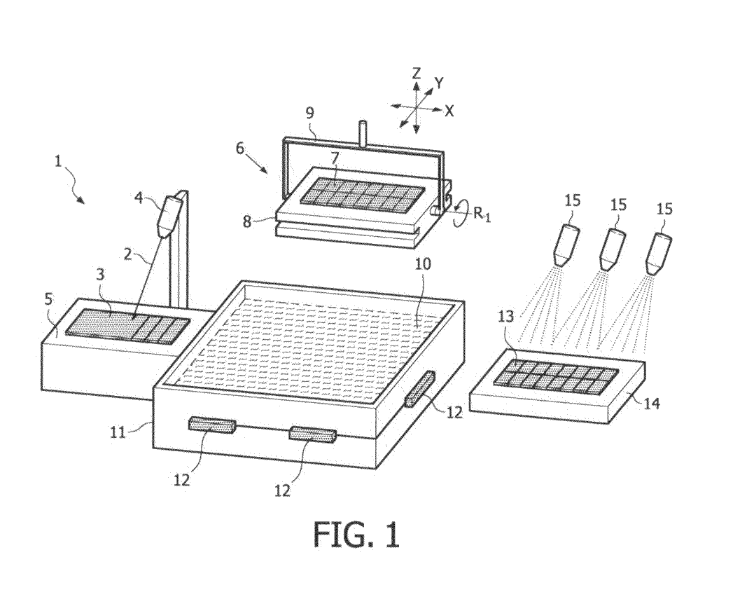

FIG. 1 shows a schematic perspective view of a device according to the present invention,

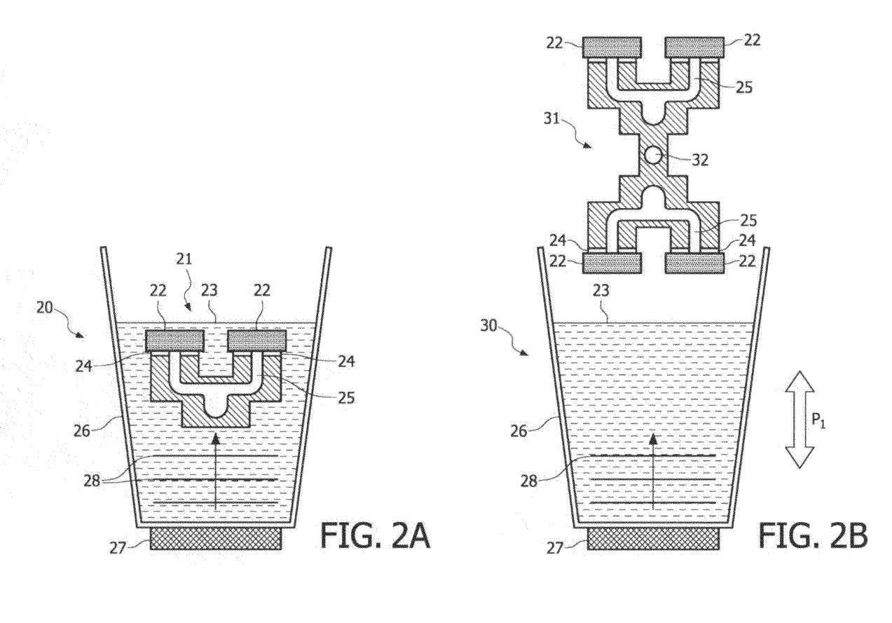

FIG. 2A shows a section through a liquid bath and a manipulator such as form part of the present invention,

FIG. 2B shows a section through an alternative embodiment variant of a liquid bath and a manipulator such as form part of the present invention,

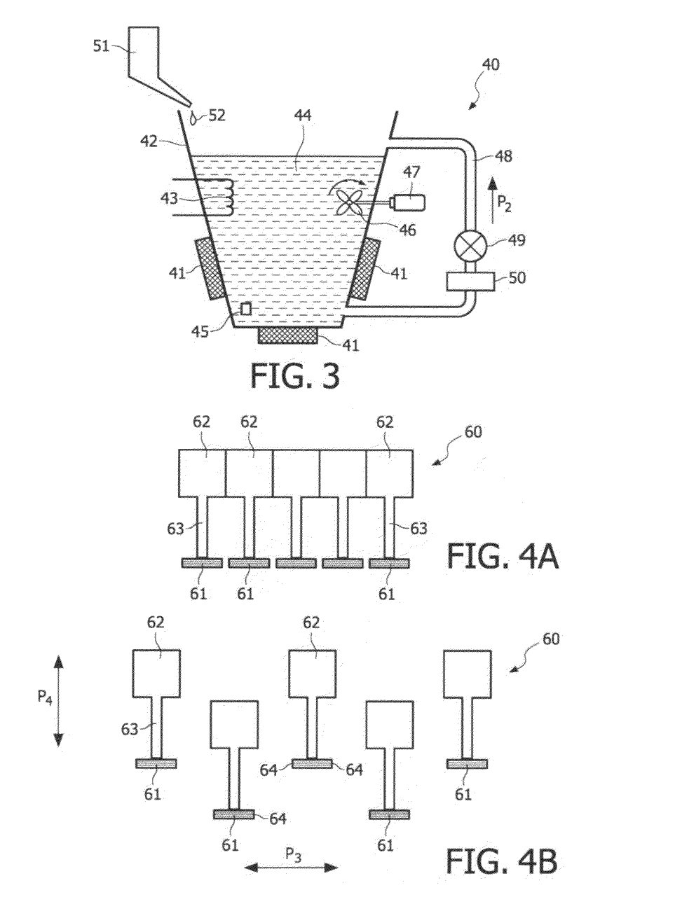

FIG. 3 shows a section through a second alternative embodiment variant of a liquid bath such as forms part of the present invention, and

FIGS. 4A and 4B shows two stages at which a manipulator according to the present invention engages a number of electronic components.

FIG. 1 shows a device 1 for processing with a laser beam 2 and subsequently cleaning combined electronic components 3. Laser beam 2 is generated by a laser source 4 which is also adapted to control laser beam 2. The combined electronic components 3 are situated on a carrier 5 and are divided by laser beam 2. A manipulator 6 engages the separated electronic components 7 after they have been divided. Manipulator 6 consists of a double manipulator head 8 (see also FIG. 2B) which is suspended rotatably (arrow R₁) in a manipulator frame 9 which is displaceable in three directions X,Y,Z. The separated electronic components 7 are then immersed in a liquid bath 10. Liquid bath 10 is formed by a liquid container 11 on which a number of ultrasonic vibration sources 12 are arranged. Electronic components 7 are cleaned intensively as a result of the immersion in liquid bath 10. The separated and cleaned electronic components 13 are subsequently set down at a discharge location 14. Blow nozzles 15 blow away any liquid possibly left behind on electronic components 13.

FIG. 2A shows a liquid bath 20 into which contaminated electronic components 22 are carried with a manipulator 21 such that they are moved below a liquid level 23. Manipulator 21 is provided with flexible seals 24, as a result of which an underpressure exerted through channels 25 acts on the contaminated electronic components 22. A vibration source 27 is arranged on the outer side of a liquid container 26, as a result of which schematically shown ultrasonic waves 28 which provide for an effective cleaning are created in liquid bath 20.

FIG. 2B shows a liquid bath 30, wherein components corresponding with the liquid bath 20 shown in FIG. 2A are designated with identical reference numerals. A manipulator 31 takes a dual form such that while an underside of manipulator 31 holds electronic components 22 under the liquid level 23, electronic components 22 can be loaded onto and/or offloaded from a top side of manipulator 31. Manipulator 31 is rotatable around a central shaft 32 such that after immersion of a batch of electronic components 22 a subsequent batch of electronic components 22 can be rapidly subjected to the ultrasonic cleaning. In order to further enhance the ultrasonic cleaning it is possible to move manipulator 31 reciprocally in vertical direction as according to arrow P₁.

FIG. 3 shows a liquid bath 40 which can form part of a device according to the present invention. Liquid bath 40 is provided with a plurality of ultrasonic vibration sources 41 which are arranged on the outside of a liquid container 42. Liquid container 42 is further provided with a heating element 43 with which the temperature of liquid 44 in liquid container 42 can be regulated. The condition of liquid 44 can be monitored by means of a sensor 45 likewise placed in liquid container 42. Sensor 45 (or multiple sensors) can form part of a measuring and control system not shown in this figure, with which for instance conditions such as the temperature, the degree of contamination and/or the composition of liquid 44 can be monitored. A turbulence can be effected in the liquid 44 in liquid container 42 by means of a propeller 46 driven by a motor 47. Liquid bath. 40 is further provided with a conduit system 48 through which liquid 44 can be pumped in a direction P₂ by means of a pump 49, as a result of which liquid 44 passes through a filter 50. The liquid 44 in liquid container 42 can hereby be set into motion and liquid 44 can be cleaned. Disposed above liquid container 42 is a dispensing unit 51 with which an additive 52 can be added to liquid 44.

FIGS. 4A and 4B both show a part of a manipulator 60 with which a number of separated electronic components 61 are engaged. In the position shown in FIG. 4A the electronic components 61 lie in a single plane; this will be the situation during engaging of electronic components 61. The manipulator consists of a plurality of segments 62, each provided with, a tubular engaging member 63. FIG. 4B shows the situation in which segments 63, which each form one engaging position, are moved horizontally (P₃) and vertically (P₄) apart, whereby the contact sides 65 of electronic components 61 newly formed as a result of the laser cutting are more readily accessible and can thus be ultrasonically cleaned in easier and better manner. It is otherwise noted that moving apart of segments 61 in only one direction is also an option.

1. Method for processing with a laser beam and subsequently cleaning electronic components, comprising the successive processing steps of:
A) forming at least one new boundary surface on an electronic component with the laser beam, and
B) placing in a liquid and ultrasonically cleaning at east a part of the newly made boundary surface.

2. Method as claimed in claim 1, wherein at least two electronic components are separated from each other during processing step A).

3. Method as claimed in claim 1, wherein the electronic components for cleaning are placed in a liquid bath.

4. Method as claimed in claim 1, wherein the whole external surface of electronic components is cleaned during processing step B).

5. Method as claimed in claim 1, wherein the electronic components are cleaned at a frequency higher than 18 kHz, preferably higher than 20 kHz.

6. Method as claimed in claim 1, wherein the electronic components for cleaning during processing step B) are carried into the liquid by a manipulator such that during the cleaning the manipulator is located on the side of the electronic components remote from an ultrasonic vibration source.

7. Method as claimed in claim 1, wherein the mutual distance between a plurality of electronic components to be simultaneously cleaned is greater during cleaning according to processing step B) than during processing step A).

8. Method as claimed in claim 1, characterized in that the liquid in which the ultrasonic cleaning is carried out is heated to more than 20° C., preferably to more than 30° C.

9. Method as claimed in claim 1, wherein the liquid in which the ultrasonic cleaning is performed consists substantially of water.

10. Method as claimed in claim 9, wherein the liquid in which the ultrasonic cleaning is performed is provided with a surfactant.

11. Method as claimed in claim 1, wherein the liquid under which the ultrasonic cleaning takes place is degassed.

12. Method as claimed in claim 1, wherein the liquid under which the ultrasonic cleaning takes place is cleaned.

13. Method as claimed in claim 1, wherein the liquid under which the ultrasonic cleaning takes place is degassed.

14. Method as claimed in claim 1, wherein liquid adhering to the electronic components is actively removed after processing step B) has been performed.

15. Device for processing and cleaning electronic components comprising at least:
a laser source for generating a laser beam, and
at least one carrier for carrying an assembly of unseparated electronic components, wherein the carrier and the laser beam are displaceable relative to each other, wherein the device is also provided with ultrasonic cleaning means and with a manipulator for displacing from the carrier to the cleaning means the electronic components processed by the laser beam.

16. Device as claimed in claim 15, wherein the ultrasonic cleaning means comprises a liquid bath and at least one vibration source connecting to the liquid bath.

17. Device as claimed in claim 16, wherein a plurality of vibration sources connect to the liquid bath.

18. Device as claimed in claim 16, wherein the manipulator is rotatable such that the electronic components for cleaning are placed in the liquid bath by the manipulator such that during cleaning the manipulator is located on the side of the electronic components remote from the vibration source.

19. Device as claimed in claim 15, wherein the manipulator takes a multiple form such that during cleaning of the electronic components an engaging part of the manipulator lies at a distance from the cleaning means.

20. Device as claimed in claim 5, wherein the device is provided with suction openings engaging by means of underpressure on the electronic components.

21. Device as claimed in claim 20, wherein the suction openings are formed by the outer ends of tubular contact elements.

22. Device as claimed in claim 15, characterized in that the manipulator is provided with a plurality of engaging positions and the mutual distance between engaging positions is adjustable.

23. Device as claimed in claim 16, wherein the ultrasonic cleaning means are provided with heating means for heating the liquid bath.

24. Device as claimed in claim 16, wherein the ultrasonic cleaning means are provided with dispensing means for supplying an additive to the liquid bath.

25. Device as claimed in claim 16, wherein the ultrasonic cleaning means are provided with at least one actuator for displacing the liquid in the liquid bath.

26. Device as claimed in claim 16, wherein the ultrasonic cleaning means are provided with cleaning means for purifying the liquid in the liquid bath.

27. Device as claimed in claim 15, wherein the device is provided with means for removing adhering liquid from the electronic components cleaned by the ultrasonic cleaning means.
